(19) United States
(12) Patent Application Publication
(10) Pub. No.: US 2006/0138528 A1
(43) Pub. Date: Jun. 29, 2006

(54) Charge trap insulator memory device

(75) Inventors: Hee Bok Kang, Daejeongwangyeok-si (KR); Jin Hong Ahn, Gyeonggi-do (KR); Jae Jin Lee, Gyeonggi-do (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 11/115,367

(22) Filed: Apr. 27, 2005

(30) Foreign Application Priority Data
Dec. 29, 2004 (KR) 10-2004-0115422

(51) Int. Cl. H01L 29/788; H01L 29/94

(52) U.S. Cl. 257/321; 257/296; 257/315

(57) ABSTRACT

A charge trap insulator memory device comprises a bottom word line, a P-type float channel formed at the bottom word line and kept at a floating state, a charge trap insulator formed on the P-type float channel, a top word line formed on the charge trap insulator in parallel with the bottom word line, and a N-type drain region and a N-type source region formed at both sides of the float channel. As a result, in the float gate memory device, a retention characteristic is improved, and cell integrated capacity is also increased due to a plurality of float gate cell arrays deposited vertically using a plurality of cell oxide layers.

### BACKGROUND OF THE INVENTION

1. Field of the Invention

The present invention generally relates to a charge trap insulator memory device, and more specifically, to a nano scale charge trap insulator memory device having an improved retention characteristic and cell integrated capacity obtained by depositing a plurality of charge trap insulator cell arrays vertically with a plurality of cell insulating layers.

2. Description of the Related Art

FIG. 1 is a cross-sectional diagram illustrating a memory cell of a conventional charge trap insulator memory device.

A memory cell of the conventional charge trap insulator memory device comprises a N-type drain region 4 and a N-type source region 6 which are formed in a P-type substrate 2, a first insulating layer 8, a charge trap insulator 10, a second insulating layer 12 and a word line 14 which are sequentially formed on the channel region.

In the above-described memory cell of the conventional charge trap insulator memory device, a channel resistance of the memory cell is differentiated by a state of charges stored in the charge trap insulator 10.

That is, since positive channel charges are induced to the channel when electrons are stored in the charge trap insulator 10, the memory cell becomes at a high resistance state to be turned off.

Meanwhile, negative channel charges are induced to the channel when positive holes are stored in the charge trap insulator 10, so that the memory cell becomes at a low resistance state to be turned on.

In this way, data are written in the memory cell by selecting kinds of charges of the charge trap insulator 10, so that the memory cell can be operated as a nonvolatile memory cell.

However, since the retention characteristic is degraded when the size of the memory cell of the conventional charge trap insulator memory device becomes smaller, it is difficult to perform a normal operation.

Specifically, since the retention characteristic of the memory cell having a charge trap insulator structure of a nano scale level becomes weaker even in a low voltage stress, a random voltage cannot be applied to a word line in a read mode.

### SUMMARY OF THE INVENTION

Accordingly, it is an object of the present invention to operate a memory cell having a charge trap insulator structure of a nano scale level in a low voltage.

It is another object of the present invention to improve cell integrated capacity by depositing a plurality of charge trap insulator cell arrays vertically with a plurality of cell insulating layers.

In an embodiment, a charge trap insulator memory device comprises a bottom word line, a float channel layer formed on the bottom word line and kept at a floating state, a charge trap insulator, and a top word line formed on the charge trap insulator in parallel with the bottom word line. In the charge trap insulator formed on the float channel layer, data are stored. Here, data are written in the charge trap insulator depending on levels of the bottom word line and the top word line, and data are read according to different channel resistance induced to the float channel depending on polarity states of charges stored in the charge trap insulator.

In another embodiment, a charge trap insulator memory device comprises a bottom word line, a first insulating layer formed on the bottom word line, a P-type float channel formed on the first insulating layer and kept at a floating state, a second insulating layer formed on the P-type float channel, a charge trap insulator, a third insulating layer formed on the charge trap insulator, a N-type drain region and a N-type source region formed at both sides of the float channel, and a top word line formed on the third insulating layer. In the charge trap insulator formed on the second insulating layer, charges are stored. Here, data are written in the charge trap insulator depending on a level of the top word line while the bottom word line is selected, and data are read according to different channel resistance induced to the float channel depending on polarity states of charges stored in the charge trap insulator.

In still another embodiment, a charge trap insulator memory device comprises a plurality of unit memory cell arrays. Each of the plurality of unit memory cell arrays includes a plurality of charge trap insulator memory cells and is deposited as a multiple layer. Here, the charge trap insulator memory cell comprises a bottom word line, a first insulating layer formed on the bottom word line, a P-type float channel formed on the first insulating layer and kept at a floating state, a second insulating layer formed on the P-type float channel, a charge trap insulator, a third insulating layer formed on the charge trap insulator, a top word line formed on the third insulating layer, and a N-type drain region and a N-type source region formed at both sides of the float channel. In the charge trap insulator formed on the second insulating layer, charges are stored. Here, data are written in the charge trap insulator depending on a level of the top word line while the bottom word line is selected, and data are read according to different channel resistance induced to the float channel depending on polarity states of charges stored in the charge trap insulator.

In still another embodiment, a charge trap insulator memory device comprises a plurality of unit memory cell arrays. Each of the plurality of unit memory cell arrays includes a plurality of charge trap insulator memory cells and is deposited as a multiple layer. Here, the charge trap insulator memory cell comprises a bottom word line, a first insulating layer formed on the bottom word line, a P-type float channel formed on the first insulating layer and kept at a floating state, a second insulating layer formed on the P-type float channel, a charge trap insulator, a third insulating layer formed on the charge trap insulator, a top word line formed on the third insulating layer, and a N-type drain region and a N-type source region formed at both sides of the float channel. In the charge trap insulator formed on the second insulating layer, charges are stored. Here, the plurality of memory cells in each of the plurality of unit memory cell arrays are connected in common to the bottom word line, data are written in the charge trap insulator depending on a level of the top word line while the bottom word line is selected, and data are read according to different channel resistance induced to the float channel depending on polarity states of charges stored in the charge trap insulator.

### BRIEF DESCRIPTION OF THE DRAWINGS

Other aspects and advantages of the present invention will become apparent upon reading the following detailed description and upon reference to the drawings in which:

FIG. 1 is a cross-sectional diagram illustrating a memory cell of a conventional charge trap insulator memory device;

FIGS. 2a and 2b are cross-sectional diagrams illustrating a unit memory cell of a charge trap insulator memory device according to an embodiment of the present invention;

FIGS. 3a and 3b are diagrams illustrating write and read operations on high level data “1” of a charge trap insulator memory device according to an embodiment of the present invention;

FIGS. 4a and 4b are diagrams illustrating write and read operations on low level data “0” of a charge trap insulator memory device according to an embodiment of the present invention;

FIG. 5 is a layout plane diagram illustrating a charge trap insulator memory device according to an embodiment of the present invention;

FIG. 6a is a cross-sectional diagram of a direction A-A′ in parallel with a word line WL of FIG. 5;

FIG. 6b is a cross-sectional diagram of a direction B-B′ perpendicular to a word line WL of FIG. 5;

FIG. 7 is a cross-sectional diagram illustrating a charge trap insulator memory device having a multiple layer structure according to an embodiment of the present invention;

FIG. 8 is a layout plane diagram illustrating a charge trap insulator memory device according to another embodiment of the present invention;

FIG. 9a is a cross-sectional diagram of a direction C-C′ in parallel with a word line WL of FIG. 8;

FIG. 9b is a cross-sectional diagram of a direction D-D′ perpendicular to a word line WL of FIG. 8;

FIG. 10 is a cross-sectional diagram illustrating a charge trap insulator memory device having a multiple layer structure according to another embodiment of the present invention.

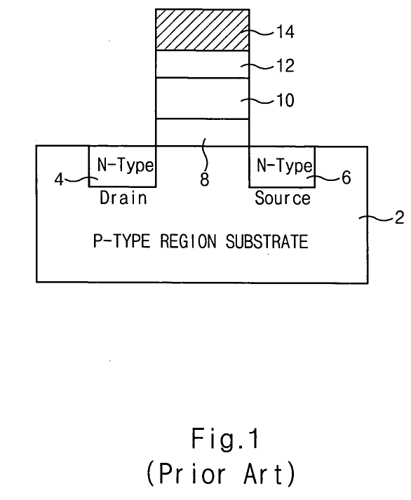

### DETAILED DESCRIPTION OF THE PREFERRED EMBODIMENTS

The present invention will be described in detail with reference to the accompanying drawings.

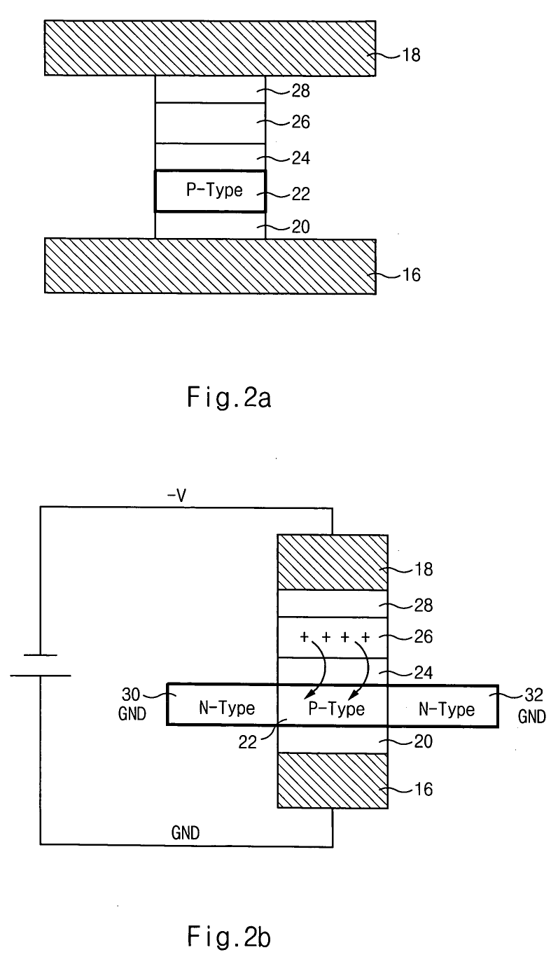

FIGS. 2a and 2b are cross-sectional diagrams illustrating a unit memory cell of a charge trap insulator memory device according to an embodiment of the present invention.

FIG. 2a is a cross-sectional diagram illustrating a unit memory cell cut in a direction parallel with a word line in a charge trap insulator memory device according to an embodiment of the present invention.

In the unit memory cell, a bottom word line 16 is formed in the bottom layer, and a top word line 18 is formed in the top layer. The bottom word line 16 is arranged in parallel with the top word line 18, and driven by the same row address decoder.

A first insulating layer 20, a float channel 22, a second insulating layer 24, a charge trap insulator 26 and a third insulating layer 28 are sequentially formed on the bottom word line 16. Here, the float channel 22 is formed with a P-type semiconductor.

FIG. 2b is a cross-sectional diagram illustrating the unit memory cell cut in a direction perpendicular to the word line in the charge trap insulator memory device according to an embodiment of the present invention.

In the unit memory cell, the bottom word line 16 is formed in the bottom layer, and the top word line 18 is formed in the top layer. The bottom word line 16 is arranged in parallel with the top word line 18.

The first insulating layer 20, the float channel 22, the second insulating layer 24, the charge trap insulator 26 and the third insulating layer 28 are sequentially formed on the bottom word line 16. Here, a N-type drain 30 and a N-type source 32 are formed at both sides of the float channel 22.

The float channel 22, the N-type drain 30 and the N-type source 32 are formed of at least one of carbon nano tube, silicon, Ge, organic semiconductors and other materials.

A channel resistance of the unit memory cell of the charge trap insulator memory device is changed depending on a state of charges stored in the charge trap insulator 26.

In other words, since positive channel charges are induced to the channel of the memory cell when electrons are stored in the charge trap insulator 26, the memory cell is turned off at a high resistance channel state.

Meanwhile, since negative charges are induced to the channel when positive holes are stored in the charge trap insulator 26, the memory cell is turned on at a low resistance channel state.

In this way, data are written by selecting kinds of charges of the charge trap insulator 26, so that the memory cell can be operated as a nonvolatile memory cell.

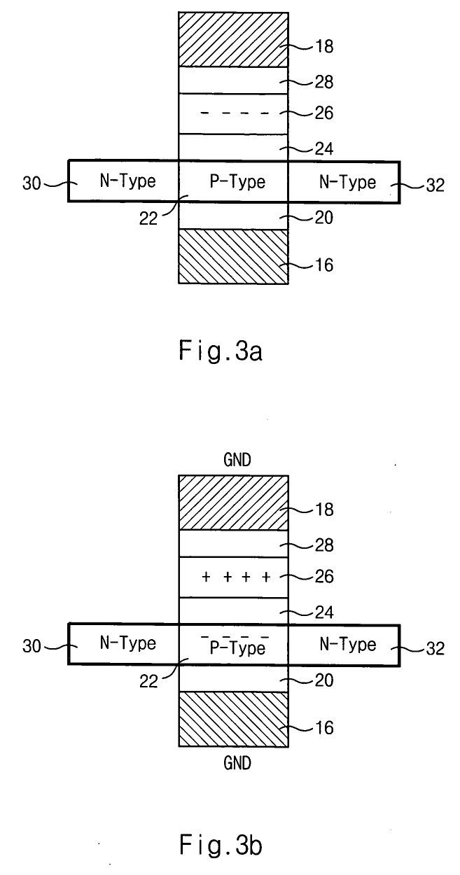

FIGS. 3a and 3b are diagrams illustrating write and read operations on high level data “1” of a charge trap insulator memory device according to an embodiment of the present invention.

FIG. 3a is a diagram illustrating the write operation of high level data “1”.

A ground voltage GND is applied to the bottom word line 16, and a negative voltage −V is applied to the top word line 18. Here, the drain region 30 and the source region 32 become at a ground voltage GND state.

In this case, when a voltage is applied between the charge trap insulator 26 and the channel region 22 by voltage division of a capacitor among the first insulating layer 20, the second insulating layer 24 and the third insulating layer 28, electrons are emitted to the channel region 22. As a result, the positive charges are accumulated in the charge trap insulator 26.

FIG. 3b is a diagram illustrating the read operation of high level data “1”.

When the ground voltage GND is applied to the bottom word line 16 and the top word line 18, negative charges are induced to the channel region 22, and the drain region 30 and the source region 32 become at the ground state, so that the channel region 22 is turned on.

As a result, in the read mode, data “1” stored in the memory cell can be read. Here, when a slight voltage difference is applied to the drain region 30 and the source region 32, the channel region 22 is turned on, so that a large amount of current flows.

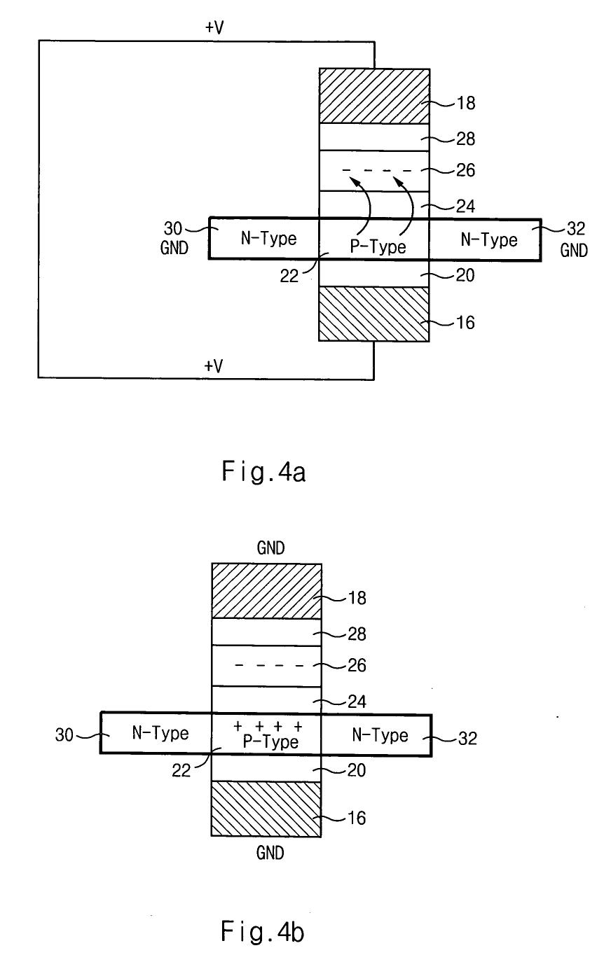

FIGS. 4a and 4b are diagrams illustrating write and read operations on low level data “0” of a charge trap insulator memory device according to an embodiment of the present invention.

FIG. 4a is a diagram illustrating the write operation of low level data “0”.

When the ground voltage GND is applied to the drain region 30 and the source region 32, and a positive voltage +V is applied to the bottom word line 16 and the top word line 18, the channel is turned on, so that a channel of the ground voltage is formed in the channel.

Since a high voltage difference is formed between the ground voltage of the channel and the positive voltage +V of the top word line 18, electrons of the channel region move toward the charge trap insulator 26, so that electrons are accumulated in the float gate 26.

Meanwhile, when the positive voltage +V is applied to the drain region 30 and the source region 32 while the high level data “1” is stored in the charge trap insulator 26, the channel is turned off, so that the channel of the ground voltage is not formed in the channel.

Since there is no voltage difference between the positive voltage of the channel at the floating state and the positive voltage +V of the top word line 18, the electrons do not move toward the charge trap insulator 26.

As a result, the charge trap insulator 26 is maintained at the previous state. That is, since the previously stored high level data “1” is maintained, the high level data “1” is written in all of the memory cells, and the low level data “0” is selectively written.

FIG. 4b is a diagram illustrating the read operation of the low level data “0”.

When the ground voltage GND is applied to the bottom word line 16 and the top word line 18, and a slight voltage difference is applied between the drain region 30 and the source region 32, the channel is turned off, so that a small amount of current flows.

In the read mode, the bottom word line 16 and the top word line 18 are at the ground voltage GND state. Since a voltage stress is not applied to the charge trap insulator 26, the retention characteristic of the memory cell is improved.

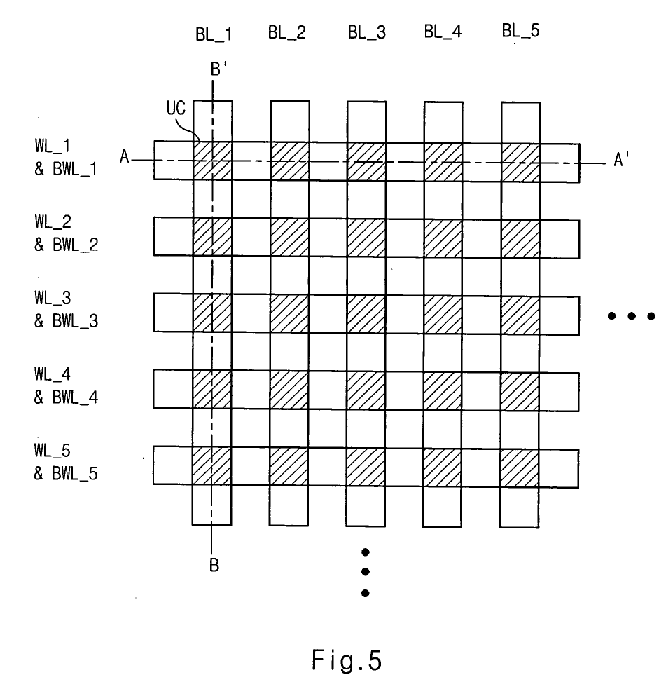

FIG. 5 is a layout plane diagram illustrating a charge trap insulator memory device according to an embodiment of the present invention.

Referring to FIG. 5, a plurality of unit memory cells UC are arranged where a plurality of word lines WL and a plurality of bit lines BL are crossed.

The top word line WL is arranged in parallel with the bottom word line BWL in the same direction, and located perpendicular to the bit line BL.

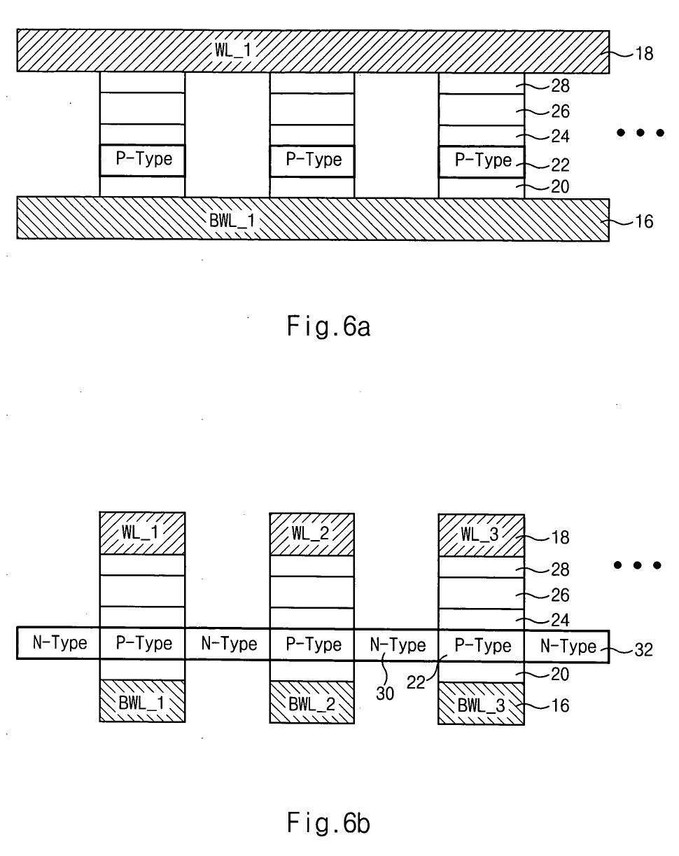

FIG. 6a is a cross-sectional diagram of a direction A-A′ in parallel with a word line WL of FIG. 5.

Referring to FIG. 6a, a plurality of unit memory cells UC are formed between the same bottom word line 16 BWL_1 and the top word line 18 WL_1 in a column direction.

FIG. 6b is a cross-sectional diagram of a direction B-B′ perpendicular to a word line WL of FIG. 5.

Referring to FIG. 6b, a plurality of unit memory cells UC are formed in the same bit line BL_1 in a row direction.

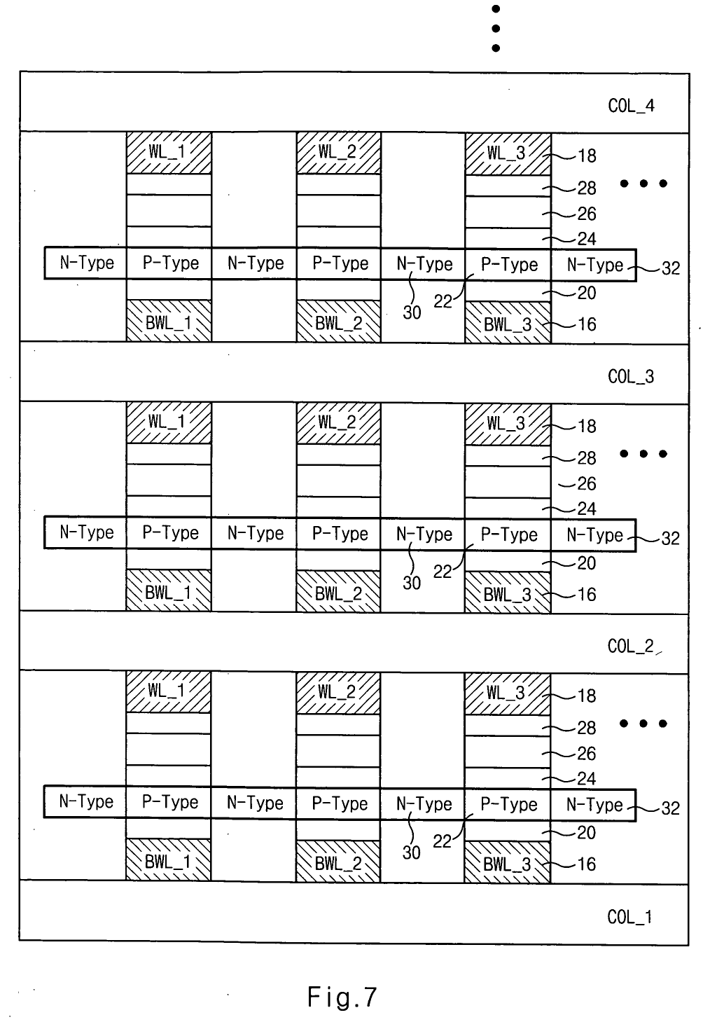

FIG. 7 is a cross-sectional diagram illustrating a charge trap insulator memory device having a multiple layer structure according to an embodiment of the present invention.

Referring to FIG. 7, a plurality of cell oxide layers COL_1˜COL_4 are formed, and a plurality of charge trap insulator cell arrays are deposited in a cross-sectional direction. As a result, the integrated capacity of the cells can be increased in the same area corresponding to the number of deposited cell arrays.

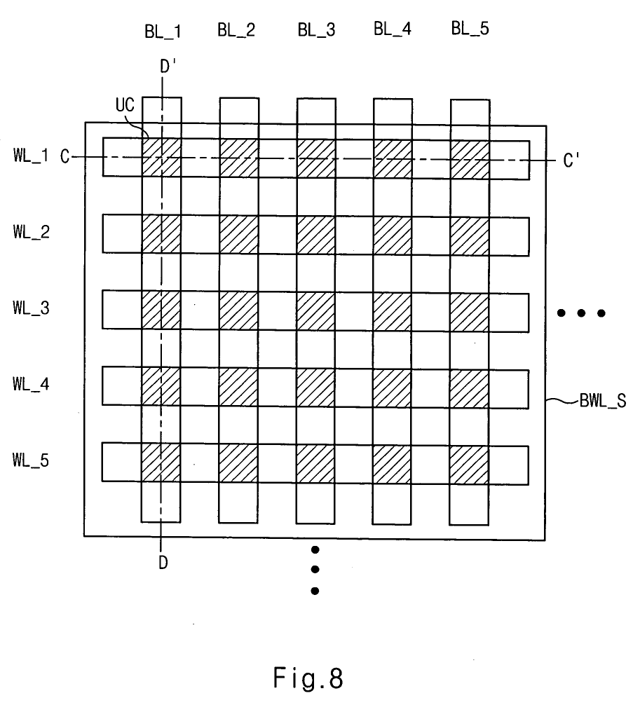

FIG. 8 is a layout plane diagram illustrating a charge trap insulator memory device according to another embodiment of the present invention.

Referring to FIG. 8, the bottom word line 16 BWL_S is used in common in a predetermined cell array range although FIG. 8 is similar to FIG. 5. The charge trap insulator memory device of FIG. 8 comprises a plurality of top word lines 18 WL in a column direction, a plurality of bit lines BL in a row direction, and a plurality of unit memory cells UC arranged where the plurality of top word lines 18 WL and the plurality of bit lines BL are crossed.

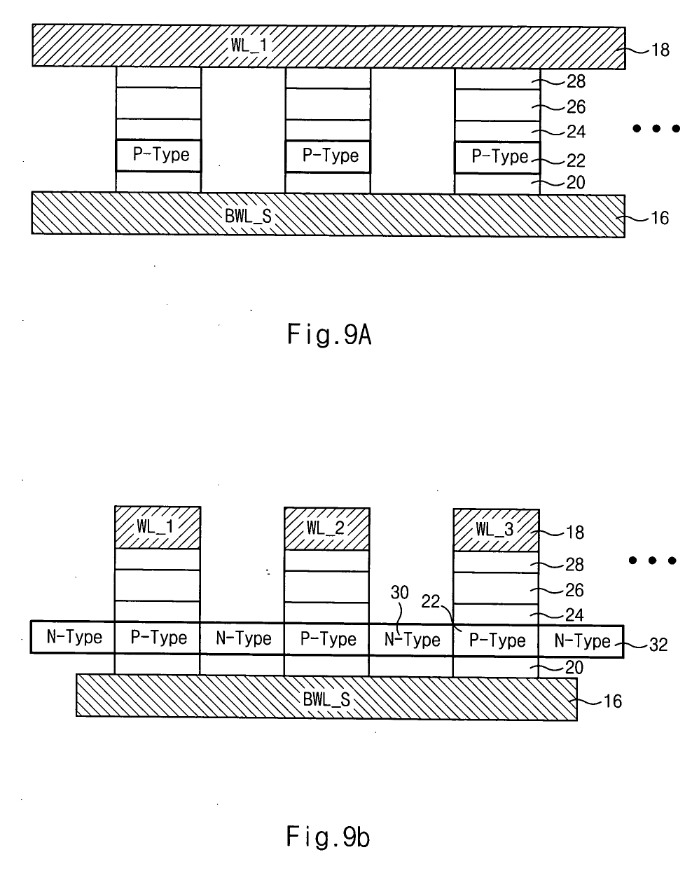

FIG. 9a is a cross-sectional diagram of a direction C-C′ in parallel with a word line WL of FIG. 8.

Referring to FIG. 9a, a plurality of unit memory cells UC are formed between the same bottom word line 16 BWL_1 and the same top word line 18 WL_1 in a column direction.

FIG. 9b is a cross-sectional diagram of a direction D-D′ perpendicular to a word line WL of FIG. 8.

Referring to FIG. 9b, a plurality of unit memory cells UC are formed in the same bit line BL_1 in a row direction. Here, the bottom word line 16 BWL_S is connected in common.

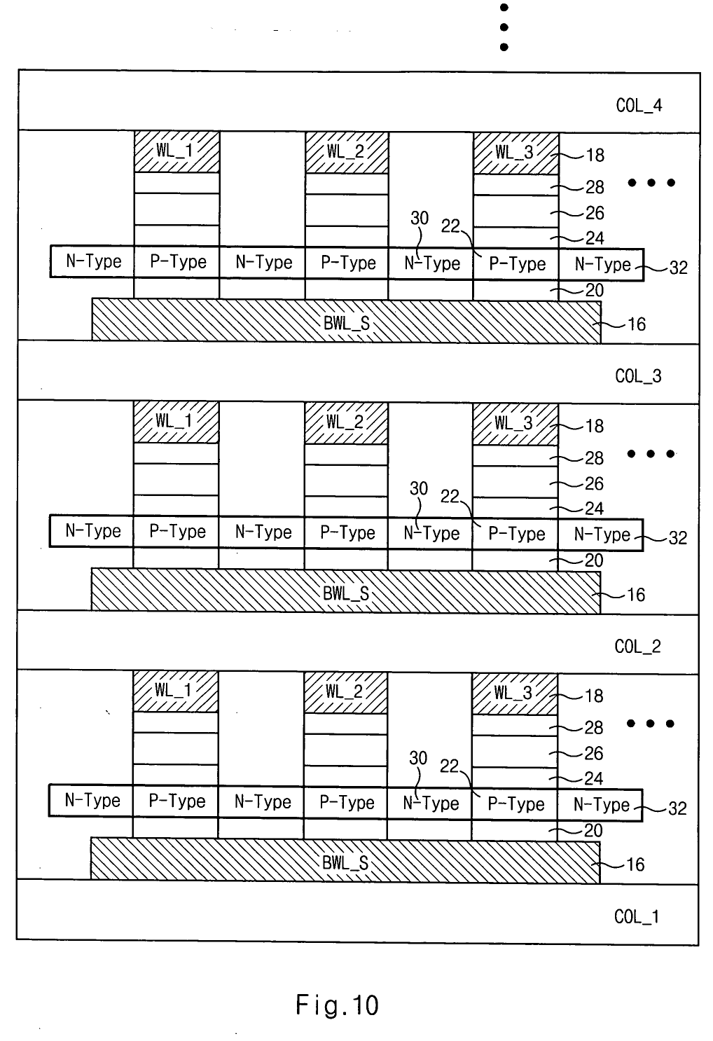

FIG. 10 is a cross-sectional diagram illustrating a charge trap insulator memory device having a multiple layer structure according to another embodiment of the present invention.

Referring to FIG. 10, the unit cell array of FIG. 8 is deposited as a multiple layer structure. Each of the unit cell arrays is separated by a plurality of cell oxide layers COL_1˜COL_4.

Although the example where the N-type drain region 30 and the N-type source region 32 are formed at both sides of the P-type channel region 22 is illustrated, a P-type drain region and a P-type source region can be formed at both sides of the P-type channel region 22.

As described above, a charge trap insulator memory device according to an embodiment of the present invention has a memory cell structure using a charge trap insulator of a nano scale level to overcome a scale down phenomenon.

Additionally, in the charge trap insulator memory device, a plurality of charge trap insulator cell arrays are deposited vertically using a plurality of cell oxide layers to improve cell integrated capacity corresponding to the number of deposited cell arrays.

While the invention is susceptible to various modifications and alternative forms, specific embodiments have been shown by way of example in the drawings and described in detail herein. However, it should be understood that the invention is not limited to the particular forms disclosed. Rather, the invention covers all modifications, equivalents, and alternatives falling within the spirit and scope of the invention as defined in the appended claims.

What is claimed is:

1. A charge trap insulator memory device comprising:
a bottom word line;
a float channel layer formed on the bottom word line and kept at a floating state;
a charge trap insulator, formed on the float channel layer, where data are stored; and
a top word line formed on the charge trap insulator in parallel with the bottom word line,
wherein data are written in the charge trap insulator depending on levels of the bottom word line and the top word line, and
data are read according to different channel resistance induced to the float channel depending on polarity states of charges stored in the charge trap insulator.

2. The charge trap insulator memory device according to claim 1, wherein the float channel layer is formed of at least one of carbon nano tube, silicon, germanium and organic semiconductor.

3. The charge trap insulator memory device according to claim 1, wherein the float channel layer comprises a N-type drain, a P-type channel, a N-type source.

4. The charge trap insulator memory device according to claim 1, wherein the float channel layer comprises a P-type drain, a P-type channel and a P-type source.

5. A charge trap insulator memory device comprising:
a bottom word line;
a first insulating layer formed on the bottom word line;
a P-type float channel formed on the first insulating layer and kept at a floating state;
a second insulating layer formed on the P-type float channel;
a charge trap insulator, formed on the second insulating layer, where charges are stored;
a third insulating layer formed on the charge trap insulator;
a top word line formed on the third insulating layer; and
a N-type drain region and a N-type source region formed at both sides of the float channel,
wherein data are written in the charge trap insulator depending on a level of the top word line while the bottom word line is selected, and
data are read according to different channel resistance induced to the float channel depending on polarity states of charges stored in the charge trap insulator.

6. The charge trap insulator memory device according to claim 5, wherein the float channel, the N-type drain region and the N-type source region are formed of at least one of carbon nano tube, silicon, germanium and organic semiconductor.

7. The charge trap insulator memory device according to claim 5, wherein when electrons are stored in the charge trap insulator, positive charges are induced to the channel region to cause a high resistance state, so that the float channel is turned off.

8. The charge trap insulator memory device according to claim 5, wherein when positive holes are stored in the charge trap insulator, negative charges are induced to the channel region to cause a low resistance state, so that the float channel is turned on.

9. The charge trap insulator memory device according to claim 5, wherein the charge trap insulator applies a positive voltage to the bottom word line, a negative voltage to the top word line, and a ground voltage to the drain region and the source region so that electrons of the float channel are introduced to write high level data.

10. The charge trap insulator memory device according to claim 9, wherein the float channel is turned on to read high level data by electrons stored in the charge trap insulator while a ground voltage is applied to the bottom word line and the top word line.

11. The charge trap insulator memory device according to claim 5, wherein the charge trap insulator applies a positive voltage to the bottom word line and the top word line, and a ground voltage to the drain region and the source region so that electrons are emitted to the float channel to write low level data.

12. The charge trap insulator memory device according to claim 11, wherein the charge trap insulator applies a positive voltage to the drain region and the source region while the positive voltage is applied to the bottom word line and the top word line, so that the previously stored high level data are maintained.

13. The charge trap insulator memory device according to claim 5, wherein the float channel is turned off depending on the polarity of the charge trap insulator to read low level data while a ground voltage is applied to the bottom word line and the top word line.

14. A charge trap insulator memory device comprising:
a plurality of unit memory cell arrays each including a plurality of charge trap insulator memory cells and deposited as a multiple layer,
wherein the charge trap insulator memory cell comprises:
a bottom word line;
a first insulating layer formed on the bottom word line;
a P-type float channel formed on the first insulating layer and kept at a floating state;
a second insulating layer formed on the P-type float channel;
a charge trap insulator, formed on the second insulating layer, where charges are stored;
a third insulating layer formed on the charge trap insulator;
a top word line formed on the third insulating layer; and
a N-type drain region and a N-type source region formed at both sides of the float channel,
wherein data are written in the charge trap insulator depending on a level of the top word line while the bottom word line is selected, and
data are read according to different channel resistance induced to the float channel depending on polarity states of charges stored in the charge trap insulator.

15. The charge trap insulator memory device according to claim 14, wherein the plurality of unit memory cell arrays are separated by a cell array insulating layer, respectively.

16. A charge trap insulator memory device comprising:
a plurality of unit memory cell arrays each including a plurality of charge trap insulator memory cells and deposited as a multiple layer,
wherein the charge trap insulator memory cell comprises:
a bottom word line;
a first insulating layer formed on the bottom word line;
a P-type float channel formed on the first insulating layer and kept at a floating state;
a second insulating layer formed on the P-type float channel;
a charge trap insulator, formed on the second insulating layer, where charges are stored;
a third insulating layer formed on the charge trap insulator;
a top word line formed on the third insulating layer; and
a N-type drain region and a N-type source region formed at both sides of the float channel,
wherein the plurality of memory cells in each of the plurality of unit memory cell arrays are connected in common to the bottom word line,
data are written in the charge trap insulator depending on a level of the top word line while the bottom word line is selected, and
data are read according to different channel resistance induced to the float channel depending on polarity states of charges stored in the charge trap insulator.

17. The charge trap insulator memory device according to claim 16, wherein the plurality of unit memory cell arrays are separated by a cell array insulating layer, respectively.
